(19) United States
(12) Patent Application Publication
(10) Pub. No.: US 2017/0134017 A1
(43) Pub. Date: May 11, 2017

(54) OVERCURRENT PROTECTION CIRCUIT

(71) Applicant: PowerbyProxi Limited, Freemans Bay, Auckland (NZ)

(72) Inventors: Lawrence Bernardo DELA CRUZ, Freemans Bay, Auckland (NZ); Rex Pius HUANG, Freemans Bay, Auckland (NZ)

(21) Appl. No.: 15/039,624

(22) PCT Filed: Nov. 7, 2014
(86) PCT No.: PCT/NZ14/00232

§ 371 Date: May 26, 2016

(30) Foreign Application Priority Data
Nov. 26, 2013 (NZ) 618250

(51) Int. Cl. H03K 17/082; H02H 3/08

(52) U.S. Cl. CPC H03K 17/0826; H02H 3/08

(57) ABSTRACT

An overcurrent protection circuit for use in a power supply system to control switching on of the circuit. The circuit is connected between a voltage source and a load. A current sensing resistor senses the current flowing to the load and a pair of thermally coupled transistor switches detect a predetermined voltage drop across the current sensing resistor when the current in the current sensing resistor exceeds a first threshold. A control switch limits the power delivered to the load from the voltage source when the pair of transistor switches detecting the predetermined voltage drop.

### FIELD OF THE INVENTION

This invention relates generally to an overcurrent protection circuit. More particularly, the invention relates to an overcurrent protection circuit for use in a power supply system, having a positive feedback to control switching on of the circuit.

### BACKGROUND OF THE INVENTION

In electrical system, it is often necessary that the system circuitry is suitably protected against the occurrence of an overcurrent. Overcurrents may arise from, for example, an unexpected increase in the load drawing power from a power supply or a short circuit occurring in the circuit.

Overcurrents result in excess currents through conductors in the system circuitry. This may increase heat generation, damage components and result in undesirable inefficiency.

Accordingly, it is desirable that the system should be protected against overcurrents. Normally, an electrical system will include a dedicated overcurrent protection circuit (OCP). OCPs will normally be the first stage in the electrical system, connecting the primary source of power (e.g. mains power) to the remaining system circuitry.

One known system for overcurrent protection is to use a current sensing resistor to sense the amount of current being provided from the primary source of power to the rest of the system. When the current through the current sensing resistor exceeds some threshold, a control switch is switched off, disconnecting the primary source of power from the rest of the system. However, a problem associated with such systems is that the components used to detect the current through the current sensing resistor are complex. For example, it may be possible to use an arrangement of op-amps, however these can be expensive, unreliable and slow. Another approach is to use an

IC chip, but these are also too expensive and complex. A further problem associated with these approaches is that the resistance of the current sensing resistor is relatively large, leading to excessive energy loss.

Accordingly, it is an object of the invention to provide an overcurrent protection circuit that is simple and reliable, which does not require a current sensing resistor with a relatively large resistance, or to at least provide the public with a useful choice.

### SUMMARY OF THE INVENTION

According to one exemplary embodiment there is provided an overcurrent protection circuit, connected between a voltage source and a load, comprising: a current sensing resistor for sensing the current flowing to the load; a pair of transistor switches provided in a single package, for detecting a predetermined voltage drop across the current sensing resistor when the current in the current sensing resistor exceeds a first threshold; and a control switch, adapted to disconnect the load from the voltage source upon the pair of transistor switches detecting the predetermined voltage drop.

It is acknowledged that the terms “comprise”, “comprises” and “comprising” may, under varying jurisdictions, be attributed with either an exclusive or an inclusive meaning. For the purpose of this specification, and unless otherwise noted, these terms are intended to have an inclusive meaning—i.e. they will be taken to mean an inclusion of the listed components which the use directly references, and possibly also of other non-specified components or elements.

Reference to any prior art in this specification does not constitute an admission that such prior art forms part of the common general knowledge.

### BRIEF DESCRIPTION OF THE DRAWINGS

The accompanying drawings which are incorporated in and constitute part of the specification, illustrate embodiments of the invention and, together with the general description of the invention given above, and the detailed description of embodiments given below, serve to explain the principles of the invention.

FIG. 1 shows an overcurrent protection circuit according to one embodiment;

FIG. 2 shows the relationship between load voltage and load current within the circuit of FIG. 1; and

FIG. 3 shows an overcurrent protection circuit with the values of components specified.

### DETAILED DESCRIPTION OF EMBODIMENTS OF THE INVENTION

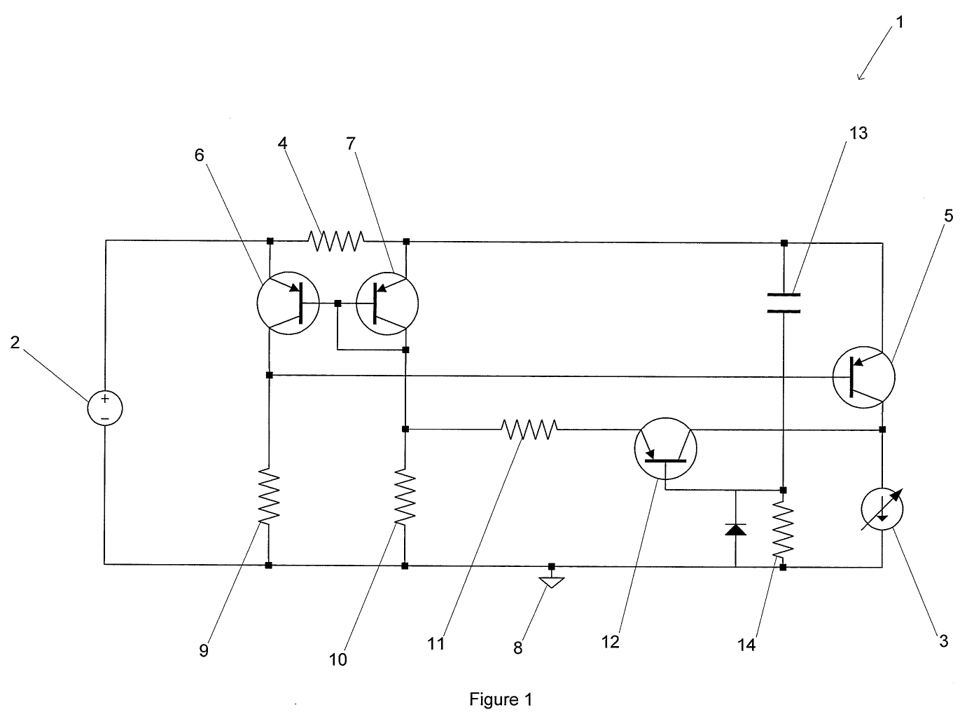

FIG. 1 shows an embodiment of an overcurrent protection (“OCP”) circuit 1 for an electrical system according to one embodiment of the present invention. At a general level, the OCP circuit has a voltage source 2 that provides power to a load 3. A current sensing resistor 4, positioned between the voltage source and the load, is used to sense the current passing to the load so as to enable detection of the sensed current exceeding a first threshold, which may occur due to some fault or change in the current demands of the load. If the current exceeds this first threshold, a control switch 5 is activated to limit the power flowing to the load thereby protecting the load from the potentially damaging effects of excess current. If and when the overcurrent condition ceases, e.g., the fault is removed or the current demands of the load change again, then the control switch is deactivated to return the full supply of power from the voltage source to the load. In one embodiment, the OCP circuit may be for a power supply system. The remainder of the description will discuss the OCP circuit in the context of a power supply, however those skilled in the art will appreciated how the OCP circuit may be suitably adapted to work within the context of other electrical systems.

The voltage source 2 may be any suitable source of power depending on the particular power supply system for which the OCP circuit 1 has been adapted. For example, according to one embodiment, the voltage source may be mains power. In another embodiment, the voltage source may be another preliminary stage in a power supply system.

It will also be appreciated that the load 3 may depend on the particular power supply system for which the OCP circuit 1 has been adapted and the invention is not limited in this respect. For example, in one embodiment, the load may be an AC-DC converter, which in turn provides power to some end load (such as powering a device). In a particular embodiment, the load may be the inductive power transmitter of an inductive power transfer system. Those skilled in the art will appreciate that such an inductive power transmitter may consist of a DC-DC converter and/or a DC-AC converter for supplying AC current to transmitting coils. The transmitting coils may generate a magnetic field, which induces current in suitably-coupled receiving coils of an inductive power receiver. The induced current may then be converted to a form suitable to be supplied to some end load (such as a device, e.g., a rechargeable battery of a smartphone).

It will be appreciated that the load 3 may draw differing amounts of current from the voltage source depending on the state of the load. For example, in the case of an inductive power transfer system, the current drawn by an inductive power transmitter may increase if the coupling between the transmitter and receiver improves, or if the end load requires more power (for example, if the charging of a battery is started). Further, the current drawn by the load may increase if there is a short circuit in the load circuitry. However, to ensure the current tolerances of the load circuitry (for example, current that could cause component damage) are not exceeded, the power provided to the load from the voltage source 2 must be limited when the current exceeds a certain level.

The current sensing resistor 4 positioned between the voltage source 2 and the load 3 in the OCP circuit is used to sense the current being supplied to the load. If a predetermined voltage drop is detected across the current sensing resistor (as will be described in more detail below), this is used to detect that the amount of current flowing from the voltage source to the load exceeds a permitted level, i.e. first threshold. The current sensing resistor may be any suitable resistor, and the invention is not limited in this respect. Those skilled in the art will appreciate that the resistance value of the resistor should be selected to ensure that a voltage drop is detected for the appropriate first threshold current.

Once an overcurrent condition has been detected, the control switch 5 positioned between the voltage source 2 and the load 3 is activated to limit the power flowing to the load. The control switch of FIG. 1 is shown as a PNP-type bipolar transistor. However, the invention is not limited to this type of switch and those skilled in the art will appreciate that the OCP circuit 1 may be adapted for other types of switches, and that the invention is not limited in this respect.

Having discussed the general parts of the OCP circuit 1, it is helpful to return to the detection of the predetermined voltage drop across the current sensing resistor 4. FIG. 1 also shows a pair of coupled transistor switches connected to either side of the current sensing resistor. In particular, a first transistor switch 6 connected to the voltage source side of the current sensing resistor 4 and a second transistor switch 7 connected to the load side of the current sensing resistor. The pair of transistor switches are in a single package. As will become apparent from the following discussion, by having the transistor switches within the same package ensures the transistor switches have approximately identical characteristics. Each transistor switch 6 7 is connected to a common ground 8 by corresponding resistors, namely a first resistor 9 and a second resistor 10. The bases of the two transistor switches are connected together. Further, the collector of the second transistor switch is connected to the bases of the pair of transistors. Together the resistor 4, the transistors 6 7 and the first and second resistors 9 10 form an overcurrent detection circuit. In the overcurrent detection circuit illustrated in FIG. 1 high-side detection is depicted such that the pair of transistor switches are PNP type bipolar transistors. The following discussion will be specific to this type of transistor switch, however those skilled in the art will appreciate how the OCP circuit may be adapted for other types of transistor switch, and that low-side detection is possible if NPN type bipolar transistors, etc., are employed. Accordingly, the invention is not limited in this respect.

The base of the first transistor 6 switch ‘tracks’ changes in the current sensing resistor 4 and the second transistor switch 7 (since the collector of the second transistor switch is connected to the base of the first transistor switch). When the current through the current sensing resistor is low, the voltage drop across the current sensing resistor is negligible. Therefore, the emitter-base voltage of the first transistor switch will be the same as the emitter-collector voltage of the second transistor switch, and the first transistor switch will be off. Since the first transistor switch is off, the base voltage of the control switch 5 is low (so the control switch is on), and power is supplied from the voltage source 2 to the load 3.

When the current being supplied from the voltage source 2 to the load 3 via the current sensing resistor 4 exceeds the first threshold, there will be a voltage drop across the current sensing resistor. Therefore, the emitter-base voltage of the first transistor switch 6 will be the same as the voltage drop across the current sensing resistor and the emitter-collector voltage of the second transistor switch 7, and the first transistor switch will switch on. Since the first transistor switch is on, the base voltage of the control switch 5 will go high, and the control switch is activated, thus limiting the power flowing to the load from the voltage source.

It will be appreciated that since the switching of the first transistor switch 6 is contingent on the second transistor switch 7, it is important that both switches have as near to identical operating characteristics. For example, that both transistor switches have about the same cut in voltages (or cut off voltages), and that these voltages will be approximately identical regardless of the operating temperature (or other environmental condition). This is achieved by having the pair of transistors thermally coupled. In one embodiment, the pair of switches may be in a single package (e.g., manufactured as a single component as opposed to separate components). This normalises the operating characteristics of the transistor switches (i.e. they are approximately identical and change in an approximately identical manner in response to environmental conditions). This allows the OCP circuit to detect very slight overcurrent conditions and to react to those conditions quickly with very little power loss

Those skilled in the art will appreciate that the values of the resistance for the first resistor 9, the second resistor 10 and the current sensing resistor 4 are selected to set the first threshold. In particular the resistance of the current sensing resistor may be relatively low compared to the resistance of current sensing resistors in existing OCP circuits, e.g. in the order of milli-Ohms. Therefore, the losses in the current sensing resistor are minimal, and therefore this OCP circuit 1 is more efficient.

The OCP circuit 1 of FIG. 1 also includes a feedback circuit to control the current in the circuit to be at a level which allows the control switch 5 to be deactivated without damage. The feedback circuit includes a feedback resistor 11, which connects the second transistor switch 7 to the load 3 via a feedback transistor switch 12. The base of the feedback transistor switch is connected to a capacitor 13 and associated resistor 14 as shown in FIG. 1. As the capacitor initially charges, the base of the feedback transistor switch will be high and the feedback transistor switch will be off. This ensures that the feedback transistor switch is switched off when the voltage source 2 is first turned on so that there is minimal current flowing through the second transistor switch, which in turn ensures that the control switch is deactivated (thus the voltage source will be initially connected to the load). This also ensures that the OCP circuit can start at full load. Once the capacitor has charged, the base to the feedback transistor switch will go low, and the feedback transistor switch will switch on. Until the voltage source is turned off, the capacitor will essentially remain charged and the feedback control switch will remain on.

When the control switch 5 is activated (as described above), the feedback transistor switch 12 remains on. The feedback circuit acts effectively as a foldback circuit which remains on whilst the voltage source 2 is active and limits the current supplied to the load 3 to be at a consistent level regardless of the operation of the control switch 5. This ensures that if conditions at the load trigger the control switch to activate, the control switch is safe to be then deactivated as the current is held by the feedback resistor 11 of the feedback circuit at a second threshold. This ensures that the control switch is not activated/deactivated as the current provided to the load varies around the first threshold. Further, it ensures that the control switch will not dissipate excessive power upon an overcurrent condition (i.e. when the load is short circuited or over loaded) and thus the control switch may be smaller and cheaper, for example, a simple and small transistor is possible rather than an op-amp or the like.

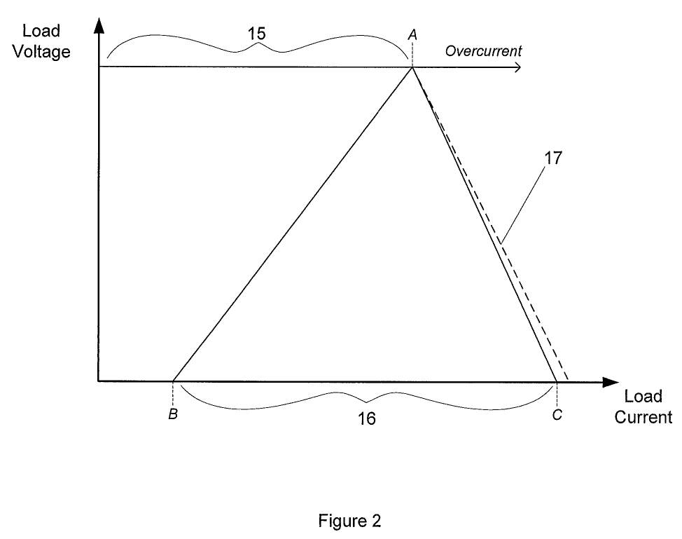

FIG. 2 shows the relationship between the output voltage across the load and the load current. When the control switch is deactivated (that is, fully switched on), the voltage is fixed to the voltage source as the load current increases, as shown in the voltage-fed region 15. If the first threshold is reached, illustrated at point A in FIG. 2, the control switch is activated (that is, partially switched off) and the feedback circuit limits the current, and therefore voltage, to reduce to the second threshold, illustrated at point B in FIG. 2. The actual value of the second threshold is determined by the combined resistance values of the feedback resistor 11 and the first and second resistors 9 and 10, and can be set from a minimum, point B in FIG. 2, to a maximum, illustrated at point C in FIG. 2, to provide a feedback region 16.

The dashed line 17 illustrated in FIG. 2 indicates what would occur in an overcurrent condition if the feedback circuit was omitted. In this situation, the control switch experiences excessive power loss caused by overcurrent. With the feedback circuit in place, point C is selected so as to be less than the maximum load current that would occur in the situation depicted by dashed line 17, such that the maximum value of the second threshold is determined in consideration of the characteristics of the control switch.

In operation of the OCP circuit of the invention, the control switch will remain deactivated until the current exceeds the first threshold. This overcurrent condition causes the control switch to activate by partially switching off. That is, the transistor of the control switch does not fully switch off because the low level of current, i.e. the value of the second threshold, that is still flowing in the circuit by operation of the feedback circuit. The control switch remains activated until the overcurrent condition has been removed, that is the current falls below the second threshold, at which point the control switch is safely deactivated as the current is limited to a level well below the maximum at which the power level at the control switch would otherwise cause damage.

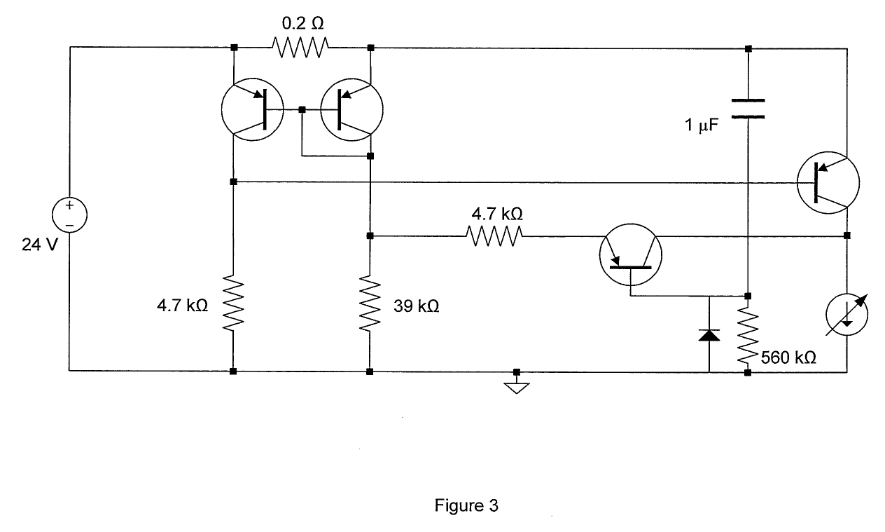

FIG. 3 shows a particular embodiment of the OCP circuit 1 of FIG. 1 with values for the components shown. In this particular embodiment, point A of FIG. 2 (i.e. the first threshold) is set at approximately 200 mA by the combined resistance values of the current sensing resistor 4, the feedback resistor 11, and the first and second resistors 9 and 10. Further, point B of FIG. 2 (i.e. the second threshold) is set at approximately 10mA by the combined resistance values of the feedback resistor 11, and the first and second resistors 9 and 10.

It will be noted that in the embodiments of the invention the resistance value of the current sensing resistor can be relatively small, e.g. about 0.2 Ohms as illustrated is FIG. 3, to provide very sensitive overcurrent detection. As described earlier, this significantly reduces the losses in the current sensing resistor as compared to conventional OCP circuits that rely on current sensing impendences. Further, in the embodiments of the invention the parallel impedance provided by the resistance values of the feedback resistor 11 and the second resistor 10 is similar to the impedance provided by the resistance value of the first resistor 9, as illustrated in FIG. 3, thereby providing a high level of overcurrent protection of the control switch, and the load circuitry as a whole.

The above described OCP circuit is relatively simple, with fewer components as compared to other known OCP circuits. The overcurrent detection and protection parts of the OCP circuit of the invention operate in both independent and interdependent fashion to both detect an overcurrent condition in a simple and effective manner and to protect the connected circuitry in a simple and reliable manner. The OCP circuit of the invention is therefore less expensive, faster and more reliable than conventional OCP circuits. Further, due to the relatively small resistance value of the current sensing resistor, there are less losses compared to other known OCP circuits.

While the present invention has been illustrated by the description of the embodiments thereof, and while the embodiments have been described in detail, it is not the intention of the Applicant to restrict or in any way limit the scope of the appended claims to such detail. Additional advantages and modifications will readily appear to those skilled in the art. Therefore, the invention in its broader aspects is not limited to the specific details, representative apparatus and method, and illustrative examples shown and described. Accordingly, departures may be made from such details without departure from the spirit or scope of the Applicant's general inventive concept.

1. An overcurrent protection circuit, connected between a voltage source and a load, comprising:
a. a current sensing resistor for sensing the current flowing to the load;
b. a pair of thermally coupled transistor switches, for detecting a predetermined voltage drop across the current sensing resistor when the current in the current sensing resistor exceeds a first threshold; and
c. a control switch, adapted to limit power delivered to the load from the voltage source upon the pair of transistor switches detecting the predetermined voltage drop.

2. An overcurrent protection circuit as claimed in claim 1, wherein the pair of transistor switches consist of:
a. a first transistor switch, connected between a voltage source end of the current sensing resistor and a first resistor connected to a common ground; and
b. a second transistor switch, connected between a load end of the current sensing resistor and a second resistor connected to a common ground,
wherein the base of the first transistor switch is coupled to the base of the second transistor switch, and the base of the second transistor switch is coupled to the base of the second transistor switch.

3. An overcurrent protection circuit as claimed in claim 1, wherein the overcurrent protection circuit includes a feedback circuit adapted to activate the control switch until the current provided to the load falls below a second threshold.

4. The overcurrent protection circuit as claimed in claim 1, wherein the pair of thermally coupled transistor switches are provided in a single package.
